(19) United States
(12) Patent Application Publication
(10) Pub. No.: US 2026/0341627 A1
(43) Pub. Date: Oct. 29, 2026

(54) Charged Particle Beam Apparatus

(71) Applicant: Hitachi High-Tech Corporation, Tokyo (JP)

(72) Inventors: Yuki IIDA, Tokyo (JP); Yuta KAWAMOTO, Tokyo (JP); Shunichi MOTOMURA, Tokyo (JP); Akira IKEGAMI, Tokyo (JP)

(21) Appl. No.: 19/654,997

(22) Filed: Apr. 22, 2026

(30) Foreign Application Priority Data
Apr. 24, 2025 (JP) 2025-071952

(51) Int. Cl. H01J 37/153; H01J 37/10; H01J 37/28

(52) U.S. Cl. CPC H01J 37/153; H01J 37/10; H01J 37/28; H01J 2237/1532

(57) ABSTRACT

An imaging unit includes a signal electron trajectory adjustment lens configured to correct a signal electron trajectory of the signal electrons, and an optical element configured to correct the signal electron trajectory of the signal electrons and to be different from the signal electron trajectory adjustment lens, a plurality of observation points are set in the sample, and the computer sets a control value common to an observation point group which is a part or all of the plurality of observation points in the signal electron trajectory adjustment lens, and sets, for each of the observation points included in the observation point group, a control value for adjusting an arrival position of the signal electron trajectory corrected by the signal electron trajectory adjustment lens to the detector.

### CROSS-REFERENCE TO RELATED APPLICATION

This application claims priority to Japanese Patent Application No. 2025-071952 filed on Apr. 24, 2025, the entire contents of which are incorporated by reference herein.

### BACKGROUND OF THE INVENTION

### 1. Field of the Invention

The present disclosure relates to a charged particle beam apparatus.

### 2. Description of the Related Art

A charged particle beam apparatus such as a scanning electron microscope (SEM) is used for measurement and inspection of a semiconductor device having a fine and three-dimensionally stacked structure. The SEM performs measurement and inspection using an image (SEM image) obtained by scanning a focused electron beam on a sample. In recent semiconductor devices, since the number of portions that need to be inspected or measured increases with the complication of a manufacturing process, further speed-up of inspection and measurement is required.

In order to speed up the inspection and the measurement by the SEM, it is effective to capture an image of a pattern with sufficient contrast. Here, signal electrons are a general term for secondary charged particles generated by an electron beam (primary electrons) interacting with a sample, and generally include secondary electrons, backscattered electrons, Auger electrons, and the like. It is known that the contrast of an SEM image can be improved by detecting appropriate signal electrons according to a structure and a shape of a pattern to be observed, and the contrast of the SEM image depends on energy of the signal electrons and depends on an emission angle (elevation angle, azimuth angle) when the signal electrons are emitted from the sample. Therefore, the contrast of the SEM image can be optimized by performing signal discrimination according to the structure and shape of the pattern to be observed, that is, by detecting signal electrons emitted at desired energy or emission angle.

However, in a state in which the sample is charged, the charging affects a trajectory of the signal electrons. As a result, the signal electrons to be originally detected are not detected due to a change in the trajectory thereof, or the signal electrons not to be originally detected are detected due to a change in the trajectory thereof, and accordingly, the contrast of the SEM image is reduced, which is a factor that increases a time required for inspection and measurement.

Patent Literature 1 discloses a technique of measuring a surface voltage of a sample surface and feeding back the surface voltage to a retarding electric field applied to the sample based on the detected surface voltage.

### CITATION LIST

### Patent Literature

PTL 1: JP2001-52642A

### SUMMARY OF THE INVENTION

Signal discrimination is important to observe an inspection and measurement target portion in a semiconductor device having such a complicated structure with high contrast, but the charging of a sample changes a trajectory of signal electrons to reduce the contrast. Therefore, it is desired to clarify the influence of the charging on a signal electron trajectory and appropriately correct the signal electron trajectory.

In the present embodiment, a charging distribution on the sample is classified into the following three types based on a difference in the influence of the charging on the signal electron trajectory. A charging 1 is a uniform charging spreading over the entire surface of a wafer. A charging 2 is a uniform charging in a field of view. Since the charging 2 is generated by the irradiation of the electron beam, for example, when raster scanning is performed, a potential distribution having a square symmetry is formed on a sample. A charging 3 is a non-uniform charging in a field of view. Since the charging 3 depends on a pattern formed on the sample, it is difficult to predict the charging distribution.

The charging 1 has a function of changing energy of signal electrons emitted from the sample. The influence of the charging 1 can be corrected by adjusting a voltage (retarding voltage) applied to a sample, as disclosed in Patent Literature 1. The charging 2 has a function of deforming a signal electron distribution of the signal electrons on a detection surface of a detector into an ellipse. Although details will be described later, if there is no charging, the signal electrons travel while spreading symmetrically with respect to a plane perpendicular to a signal electron optic axis, and thus the signal electron distribution of the signal electrons on the detection surface of the detector becomes a perfect circle, whereas the symmetry of the signal electron distribution on the detection surface of the detector deteriorates due to the influence of the charging 2. In addition, since the energy of the signal electrons is also changed in the same manner as in the charging 1, this also causes a trajectory change. The charging 3 has a function of deflecting the signal electrons in different directions at each point in the field of view and deteriorating the symmetry of the signal electron distribution on the detection surface of the detector. Similarly to the charging 1 and the charging 2, the charging 3 also changes the energy of the signal electrons, which also causes the trajectory change.

Even if the influence of the charging 1 is prevented by adjusting the retarding voltage with respect to the charging 1, the following trajectory change occurs in the signal electron trajectory due to the generation of the charging 2 and the charging 3. A trajectory change 1 is a trajectory change caused by an energy change of the signal electrons due to a difference in potential of an emission position of the signal electrons. A trajectory change 2 is a trajectory change in which the signal electron distribution on the detection surface of the detector is deformed into an elliptical shape by the potential distribution having symmetry around the emission position of the signal electrons due to the charging 2. A trajectory change 3 is a trajectory change in which the signal electron distribution on the detection surface of the detector changes complicatedly (into a shape having no symmetry) due to a local deflection field distribution on the sample by the charging 3.

A charged particle beam apparatus according to an embodiment of the present disclosure includes: an imaging unit configured to irradiate a sample with a charged particle beam and including a detector configured to detect signal electrons emitted from the sample; and a computer configured to control the imaging unit. The imaging unit includes a signal electron trajectory adjustment lens configured to correct a signal electron trajectory of the signal electrons, and an optical element configured to correct the signal electron trajectory of the signal electrons and to be different from the signal electron trajectory adjustment lens, a plurality of observation points are set in the sample, and the computer sets a control value common to an observation point group which is a part or all of the plurality of observation points in the signal electron trajectory adjustment lens, and sets, for each of the observation points included in the observation point group, a control value for adjusting an arrival position of the signal electron trajectory corrected by the signal electron trajectory adjustment lens to the detector.

According to the present disclosure, there is provided a charged particle beam apparatus capable of optimizing a contrast of an image by correcting changes in signal electron trajectories in various aspects caused by sample charging with a plurality of types of optical elements. Other problems and novel features will become apparent from descriptions of the present specification and the accompanying drawings.

### BRIEF DESCRIPTION OF THE DRAWINGS

FIG. 1 is a schematic configuration diagram of an SEM for correcting a signal electron trajectory by charge;

FIG. 2A is a diagram illustrating charging generated by scanning with an electron beam;

FIG. 2B is a diagram illustrating the charging generated by scanning with the electron beam;

FIG. 3 is a diagram schematically showing distortion of a signal electron distribution due to charging;

FIG. 4 is a schematic configuration diagram of an imaging unit of an SEM for correcting a signal electron trajectory by charging;

FIG. 5 is a schematic configuration diagram of the imaging unit of the SEM for correcting the signal electron trajectory by charging;

FIG. 6 is a schematic configuration diagram of the imaging unit of the SEM for correcting the signal electron trajectory by charging;

FIG. 7 shows an example of a GUI for correcting the signal electron trajectory by charging;

FIG. 8 shows an example of a GUI for acquiring control values of a stigmator and a signal electron trajectory adjusting deflector; and

FIG. 9 shows an example of an inspection sequence.

### DESCRIPTION OF EMBODIMENTS

As described above, an influence of charging on a signal electron trajectory has a plurality of aspects due to a charging distribution. In the embodiments described below, the signal electron trajectory is corrected separately for each of a plurality of modes.

### Embodiment 1

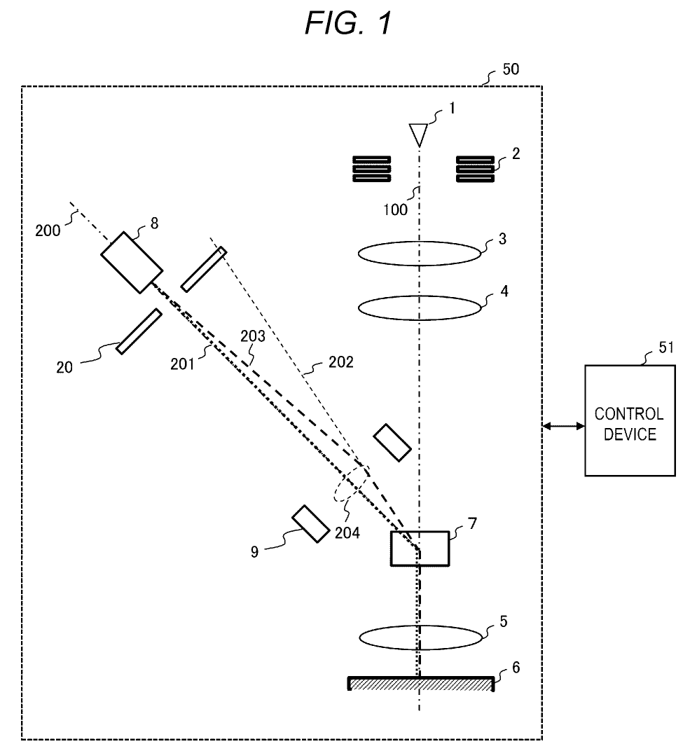

In the present embodiment, a trajectory change caused by a difference in energy of signal electrons is corrected. FIG. 1 shows a configuration example of an SEM. The SEM includes an imaging unit 50 that irradiates a sample with an electron beam and detects signal electrons, and a control device 51 that controls each mechanism of the imaging unit 50 and forms an SEM image based on a detection signal from the imaging unit 50. For example, the control device 51 is a computer connected to an output device such as a display or an input device such as a keyboard or a pointing device, and controls an operation of each mechanism of the imaging unit 50.

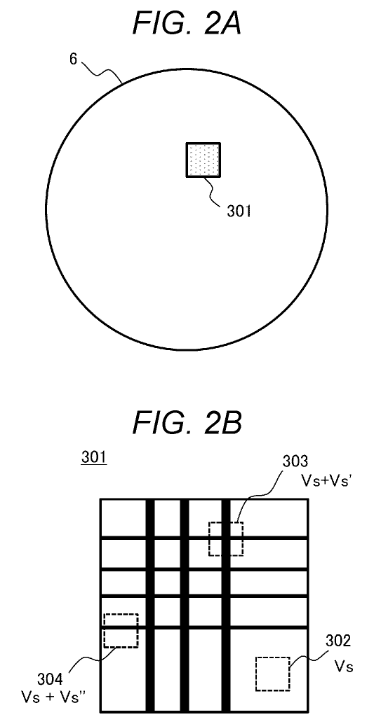

In order to enhance signal discrimination of the signal electrons, it is effective to spatially separate a primary optical system and a detection system and dispose an optical element that acts only on the signal electrons in the detection system. Here, the primary optical system refers to an optical system that includes a signal electron separation element and irradiates a sample with an electron beam from an electron source, and the detection system refers to an optical system in which signal electrons separated from an optic axis of the primary optical system by the signal electron separation element travel toward a detector. The imaging unit 50 includes such an electron optical system. The primary electrons emitted from the electron source 1 are accelerated by an acceleration electrode 2 and then focused on an object surface position of an objective lens 5 by at least one condenser lens (here, two condenser lenses 3 and 4 are shown). Meanwhile, the signal electrons emitted from a wafer 6 first travel toward the electron source 1 and are separated from a primary electron optic axis 100 by the signal electron separation element 7. FIG. 1 shows an example in which signal electrons are deflected by 45° by the signal electron separation element 7. As the signal electron separation element 7, a known deflector such as an electrostatic deflector, an electromagnetic deflector, a Wien filter combining an electrostatic deflector and an electromagnetic deflector, or a magnetic field sector can be used. Instead of being implemented as one deflector, multi-stage deflection by a plurality of deflectors may be adopted. A detector 8 is disposed on a signal electron optic axis 200. As the detector 8, an ET detector or a semiconductor detector generally used as a secondary electron detector can be used. Alternatively, a camera using a CMOS sensor or a CCD sensor may be used as the detector 8 so that a projection image can be observed. An aperture 20 is disposed in a path of signal electrons to pass only signal electrons in the vicinity of the signal electron optic axis 200. The aperture 20 can be disposed on the primary electron optic axis 100 between the objective lens 5 and the signal electron separation element 7 or on the signal electron optic axis 200 between the signal electron separation element 7 and the detector 8. When the shape of an aperture of the aperture 20 is a perfect circle and there is no distortion in the signal electron distribution, a luminance distribution of the signal electrons passing through the aperture 20 on a detection surface of the detector 8 is a perfect circle. Charging generated on a sample will be described with reference to FIGS. 2A and 2B. As shown in FIG. 2A, when the wafer 6 is scanned with an electron beam (primary electrons), the charging (charging 2) occurs in a scanned region 301. A uniform component of the charging generated in the region 301 is denoted by Vs. FIG. 2B is an enlarged view of the region 301. In the region 301, patterns that may affect the charging distribution, such as wiring and grooves, are schematically shown by vertical and horizontal lines. In addition to a region 302 having the charging Vs, a region 303 having the charging (Vs + Vs') and a region 304 having the charging (Vs + Vs'') are present in the region 301 depending on the pattern, and non-uniform charging (charging 3) occurs in the field of view. Since the energy of the signal electrons changes depending on a potential at the emission position, energy E of the signal electrons has a width of Emin < E < Emax in the field of view due to charging. An energy width may be from several tens of volts to 100 volts or more. When electrons having different energies pass through the deflector, a deflection angle varies depending on a magnitude of the energy of the electrons. This is called color dispersion. Since a control voltage value and/or a control current value (collectively referred to as a control value) of the signal electron separation element 7 is set such that the signal electron trajectory 201 that is not affected by charging reaches the detector 8, the deflection angle of the signal electrons whose energy is changed changes due to the color dispersion. As a result, a certain amount of signal electrons that are separated from the signal electron optic axis 200 and do not reach the detector 8 is generated, and a detection signal amount changes from the detection signal amount in a state in which there is no charging.

Therefore, a signal electron trajectory adjustment lens 9 is disposed at a position that does not act on the primary optical system. The signal electron trajectory adjustment lens 9 has a lens action at least in a color dispersion generation direction of the signal electron separation element 7. For example, the signal electron trajectory 202 largely separated from the signal electron optic axis 200 by the signal electron separation element 7 becomes a signal electron trajectory 203 reaching the detector 8 by the action of the signal electron trajectory adjustment lens 9. The signal electron trajectory adjustment lens 9 may be either an electrostatic lens or an electromagnetic lens, or may have a multipole structure. By setting the control value applied to the signal electron trajectory adjustment lens 9 so that the trajectory generated at a color dispersion generation position of the signal electron separation element 7 reaches the detector 8, it is possible to correct a trajectory change caused by a difference in the energy of the signal electrons. For example, if a range of the energy E of the signal electrons to be corrected is defined as Emin < E < Emax, and a variation of the signal electron trajectory due to the color dispersion in that case occurs in the range 204, an arrival position can be corrected without changing an operation condition of the optical element for each energy E of the signal electrons by setting an intensity of the signal electron trajectory adjustment lens 9 so that the signal electrons passing through a range 204 are focused on the detection surface of the detector 8.

As the control value applied to the signal electron trajectory adjustment lens 9, a value obtained by simulation in advance or a value obtained by experiment may be used. When the control value is obtained by experiment, a signal electron arrival position is measured while changing a retarding voltage value applied to the sample, and the control value applied to the signal electron trajectory adjustment lens 9 can be obtained to minimize an arrival position deviation in the detector 8. Since an optical element that changes the trajectory of electrons, such as an objective lens, causes the color dispersion, the optical element that corrects the signal electron trajectory is not limited to the signal electron separation element 7. By adding a signal electron trajectory adjustment lens closer to the detector 8 than the optical element that changes the signal electron trajectory, it is possible to similarly correct the trajectory change generated at the color dispersion generation position of the optical element.

### Embodiment 2

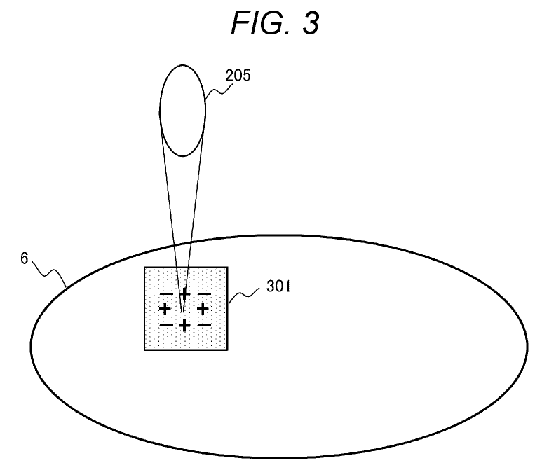

In the present embodiment, the deterioration of the symmetry of the signal electron distribution due to the charging 2 is corrected. FIG. 3 shows a signal electron trajectory 205 having one point in the region 301 as an emission position. A region 301 indicates a field of view shape of the SEM, and when raster scanning is performed by an electron beam (primary electron), the region 301 becomes a quadrangle, and the uniform charging Vs is generated. In the region 301 where the uniform charging Vs is generated, a potential distribution with four-fold rotational symmetry occurs, and the signal electron distribution on the detection surface of the detector 8 changes to an elliptical shape. This can be interpreted that the signal electron distribution is deformed due to the occurrence of astigmatism. Therefore, a stigmator may be used to recover the symmetry of the signal electron distribution. A pole of the stigmator may be either an electrostatic type or an electromagnetic type.

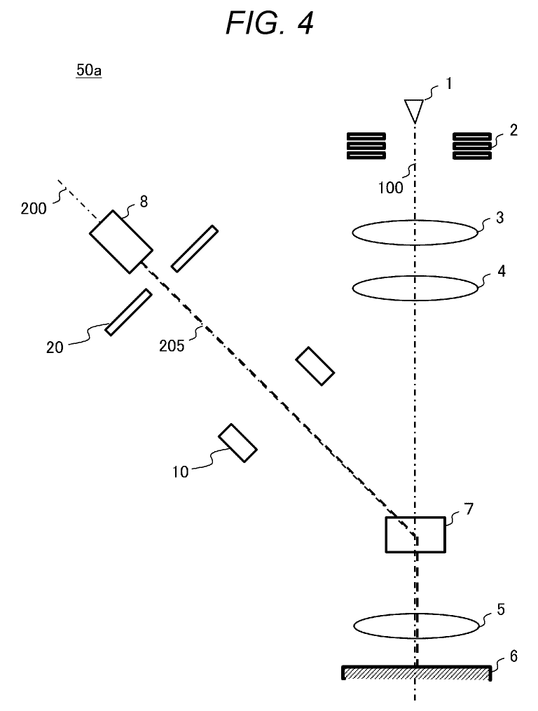

FIG. 4 is a configuration example of an imaging unit 50a that corrects the deterioration of symmetry of the signal electron distribution due to charging. The imaging unit 50a includes a stigmator 10 for correcting astigmatism of a signal electron trajectory. An image of primary electrons is acquired by the detector 8, and a control value to be applied to the stigmator 10 can be determined so that the luminance distribution becomes a perfect circle.

The stigmator 10 needs to be disposed so as not to affect the primary optical system. In the case of the electron optical system shown in FIG. 4 in which the primary optical system and the detection system are separated, it is desirable to dispose the stigmator 10 in a column of a detection system through which the primary electrons do not pass. Alternatively, when the stigmator is installed at a position where both the primary electrons and the signal electrons pass through but the primary electrons are focused, it is possible to significantly reduce the influence on the trajectory of the primary electrons generated when a control voltage or a control current is applied to the stigmator 10. For example, if the primary electrons are focused in the signal electron separation element 7, control of astigmatism correction may be added to the signal electron separation element 7.

### Embodiment 3

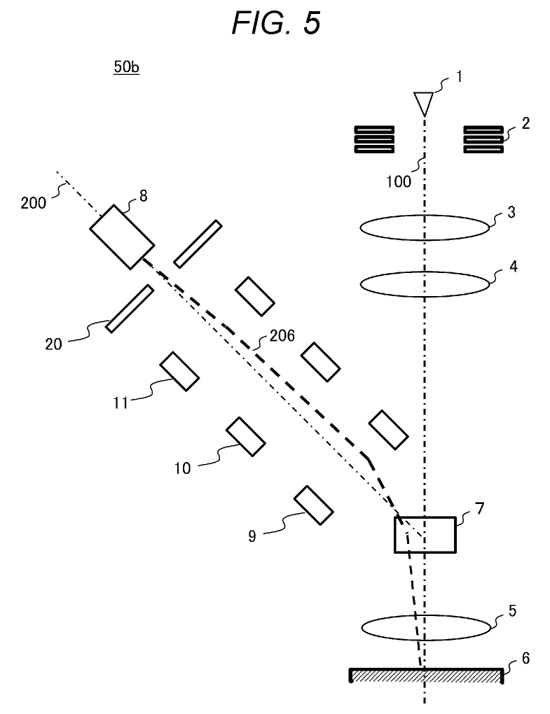

In the present embodiment, the trajectory change (trajectory changes 1 to 3) of the signal electron trajectory generated in the state in which the charging 2 and the charging 3 are generated is corrected. FIG. 5 is a configuration example of an imaging unit 50b that corrects the trajectory changes 1 to 3.

The energy width of the signal electrons is Emin < E < Emax. The energy width may be an energy width assumed in a certain observation field of view, or may be a maximum energy width assumed in a wafer surface in the case of a sample such as a semiconductor wafer. As described in Embodiment 1, the control voltage or the control current is applied to the signal electron trajectory adjustment lens 9 so that the change in the arrival position of the signal electrons due to the energy change in the signal electrons is corrected.

The trajectory changes of the signal electrons that cannot be corrected by the signal electron trajectory adjustment lens 9 include the trajectory change 2 and the trajectory change 3. As the influence of the non-uniform charging in the field of view described as the charging 3, a case in which the deterioration of the symmetry of the signal electron distribution is not remarkable and the entire signal electron distribution on the detection surface of the detector 8 is translated is considered. Therefore, as described in Embodiment 2, the signal electron distribution is corrected using the stigmator 10. Further, when a center position of the signal electron distribution on the detection surface of the detector 8 is separated from the signal electron optic axis 200 due to the influence of the non-uniform charging, position adjustment is performed by the signal electron trajectory adjusting deflector 11 so that a center of the signal electron distribution coincides with the center position of the detection surface of the detector. The signal electron trajectory adjusting deflector 11 is disposed in a column of the detection system so as not to affect the primary optical system. The signal electron trajectory adjusting deflector 11 may be either an electrostatic deflector or an electromagnetic deflector. As a result of the control, a signal electron trajectory 206 reaching the detector 8 is obtained.

Here, the arrangement of the signal electron trajectory adjustment lens 9, the stigmator 10, and the signal electron trajectory adjusting deflector 11 disposed between the signal electron separation element 7 and the detector 8 is not limited to the order shown in FIG. 5. The signal electron separation element 7, the stigmator 10, the signal electron trajectory adjustment lens 9, and the signal electron trajectory adjusting deflector 11 can be disposed in any order, or may be disposed so that the positions acting on the signal electrons overlap each other on the signal electron optic axis 200.

As described above, the change given to the signal electron trajectory varies depending on the charging distribution on the sample. Therefore, in order to correct the signal electron trajectory, it is desirable to perform correction separately for each change using different optical elements. According to the configuration of the present embodiment, the signal electron trajectory change can be appropriately corrected according to the factor, and appropriate signal discrimination can be performed.

### Embodiment 4

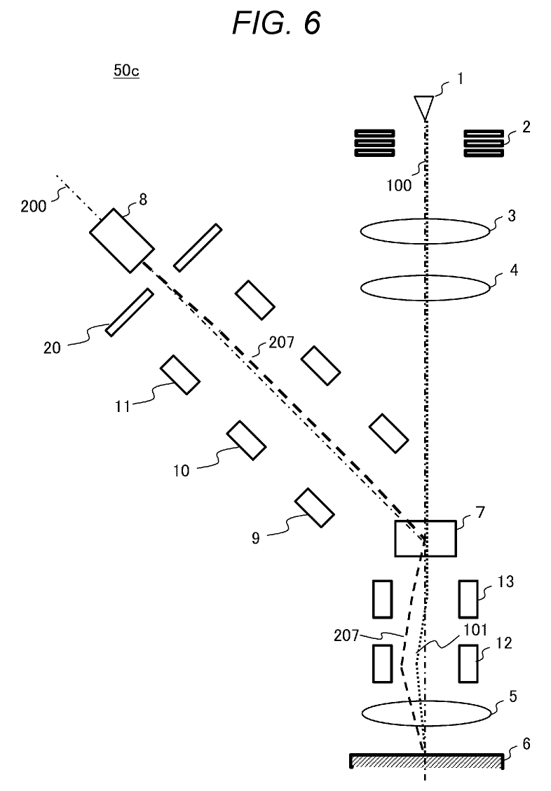

In the present embodiment, in the SEM including columns separated by the primary optical system and the detection system, the trajectory of the signal electrons is deviated from a deflection fulcrum of the signal electron separation element 7 due to a large deflection action by charging, and thus the signal electron trajectory in a case in which a resolution of an SEM image is deteriorated is corrected. FIG. 6 is a configuration example of an imaging unit 50c that corrects such a signal electron trajectory. A detection system column shows an example of the detection system described in Embodiment 3, and the configuration of the detection system may be Embodiment 1, Embodiment 2, or a combination thereof.

In the imaging unit 50c, signal electron trajectory adjusting deflectors 12 and 13 are disposed between the wafer 6 and the signal electron separation element 7. A signal electron trajectory 207 is deflected off-axis due to charging of the wafer. The signal electron trajectory adjusting deflector 12 swings back toward the deflection fulcrum of the signal electron separation element 7. Meanwhile, the primary electrons are deflected by a deflection field of the signal electron trajectory adjusting deflector 12. Therefore, the primary electrons are deflected off-axis from the primary electron optic axis 100 by the signal electron trajectory adjusting deflector 13, and are swung back toward an observation portion on the sample by the signal electron trajectory adjusting deflector 12 (a primary electron trajectory 101). Since the signal electrons are also affected by the deflection field of the signal electron trajectory adjusting deflector 13, by adjusting a ratio of the deflection fields of the signal electron trajectory adjusting deflector 12 and the signal electron trajectory adjusting deflector 13, the signal electron trajectory 207 affected by the charging is swung back to the deflection fulcrum of the signal electron separation element 7, and the arrival position of the primary electron trajectory 101 on the wafer is not deviated.

The signal electron trajectory adjusting deflectors 12 and 13 may be either an electrostatic deflector or an electromagnetic deflector. When an incident angle of the signal electrons to the signal electron separation element 7 becomes a problem, an electrostatic or electromagnetic deflector may be further added between the wafer 6 and the signal electron separation element 7 to adjust the incident angle to the signal electron separation element 7.

A method for performing inspection or measurement (hereinafter, collectively referred to as observation including inspection and measurement) of a semiconductor wafer using the SEM including the imaging unit described as Embodiments 1 to 4 will be described above. When a plurality of portions having different patterns formed on a semiconductor wafer are observed, a change in signal electron trajectory due to charging is corrected.

The energy width of the energy E of the signal electrons assumed when all the portions to be observed are included is Emin < E < Emax. A control value of the signal electron trajectory adjustment lens 9 is applied so that the trajectory change due to the color dispersion of the signal electrons having the energy width is corrected. Deterioration of the symmetry of the signal electron distribution is corrected by the stigmator 10, and the control value applied to the stigmator 10 needs to be set according to a charging amount for each observation point. Therefore, for each observation point, an image of primary electrons is acquired in advance in a state in which a control value is applied to the signal electron trajectory adjustment lens 9 to cause the signal electron trajectory adjustment lens 9 to act, and a control value of the stigmator 10 is acquired. When there is a concern about damage or a change in a charging state when preliminary data is acquired at the observation point, an image of the primary electrons may be acquired at a position in the vicinity of the observation point.

Even when the correction by the signal electron trajectory adjustment lens 9 and the stigmator 10 is performed, if the field of view is deviated, the position adjustment is performed using the signal electron trajectory adjusting deflectors 11, 12, and 13 so that the center of the signal electron distribution coincides with the center position of the detection surface of the detector. The control values applied to the signal electron trajectory adjusting deflectors 11, 12, and 13 also need to be set for each observation point. For the control values applied to the signal electron trajectory adjusting deflectors 11, 12, and 13, the control value is applied to the signal electron trajectory adjustment lens 9 for each observation point to cause the signal electron trajectory adjustment lens 9 to act, and the control value of the observation point is applied to the stigmator 10 to cause the stigmator 10 to act, and in this state, an image of primary electrons is acquired in advance to acquire the control values of the signal electron trajectory adjusting deflectors 11, 12, and 13.

Since it may take an enormous amount of time to acquire control values in advance at all observation portions on the semiconductor wafer, a GUI may be displayed on a display connected to the control device 51 to designate an observation point at which the signal electron trajectory is corrected. For example, the observation point can be designated based on coordinates of a defect (defect ID). Alternatively, when a defect type is identified by executing the inspection of the semiconductor wafer by an optical inspection device or the like, the defect type may be designated to designate the observation point. In the preliminary acquisition, it may be effective to individually set observation conditions of the SEM in order to form the charging state and improve the reliability of the correction value. At this time, the imaging conditions (imaging magnification, scanning conditions, probe current, acceleration voltage, and the like) of the SEM may be changed for each observation portion from the GUI. These settings may be made by directly inputting setting values and conditions using a GUI, or by designating and reading a file. In addition, it is not always necessary to perform all the corrections for the signal electron trajectory according to an object to be observed, and only a part of the corrections may be performed.

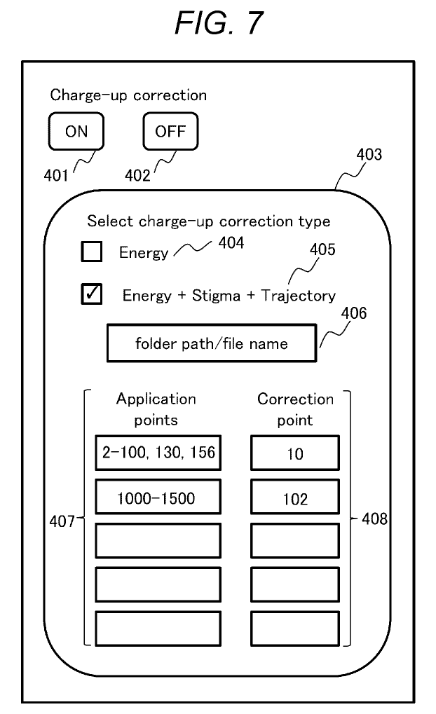

FIG. 7 shows an example of a GUI for performing charging correction. By selecting either an ON tab 401 or an OFF tab 402, whether to perform charging correction is selected. When the ON tab 401 is selected, a panel 403 is displayed to set execution contents of the charging correction. Check boxes 404 and 405 are used to select a type of charging correction to be performed. When the check box 404 is selected, the trajectory change (trajectory change 1) associated with the energy change is corrected. When the check box 405 is selected, in addition to the trajectory change associated with the energy change, the symmetry of the signal electron distribution and the trajectory change (trajectory changes 2 and 3) that changes the arrival position are corrected. Therefore, when the check box 405 is selected, a control value for each observation point is required. When there is a control value acquired in advance, for example, a directory of a file in which the control value is stored may be set in a file setting field 406. On the other hand, when the control value is acquired during observation, the coordinates of the observation point are designated in each field of an observation coordinate designation field 407, and the coordinates for acquiring the control value for performing the charging correction are designated in the corresponding field of a control value acquisition coordinate designation field 408 for acquiring the control value. In this case, when observing the observation point at the coordinates designated in each field of the observation coordinate designation field 407, the control value acquired at the coordinates designated in the corresponding field of the control value acquisition coordinate designation field 408 is used.

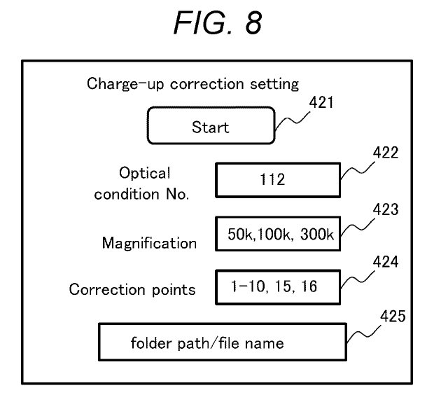

FIG. 8 shows an example of a GUI for acquiring control values input to the stigmator 10 and the signal electron trajectory adjusting deflectors 11, 12, and 13. In an optical condition designation field 422, an optical condition number in which the acceleration voltage and the probe current are set is designated. An imaging magnification of the SEM image to be acquired is designated in an imaging magnification designation field 423. A plurality of imaging magnifications can be designated. Coordinates for acquiring control values for correcting the signal electron trajectory are designated in a control value acquisition coordinate designation field 424. When a start button 421 is pressed, acquisition of the control value is started, and the control value is stored in the directory described in a file setting field 425.

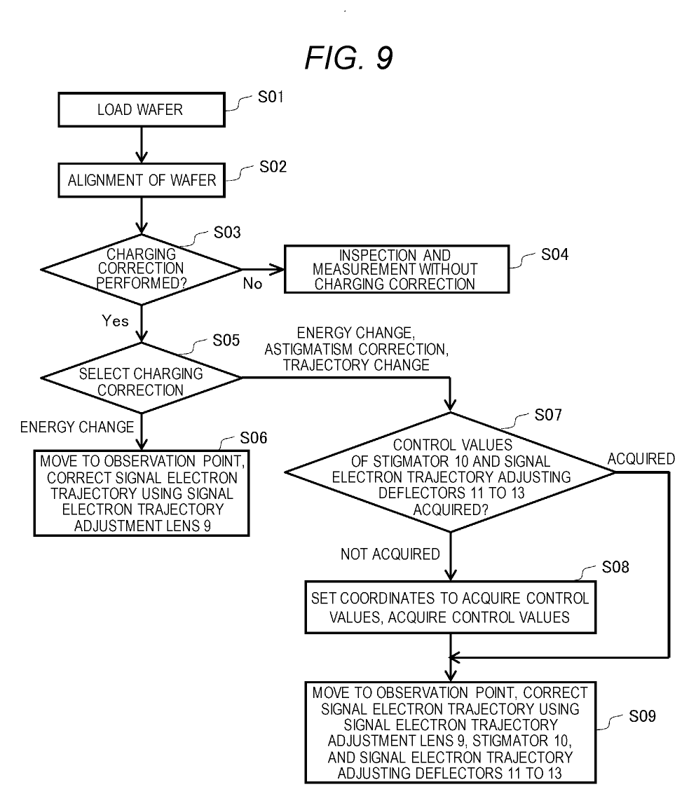

FIG. 9 shows an example of an inspection sequence. A semiconductor wafer is loaded (S01), and alignment is performed (S02). Whether to perform charging correction is selected (S03), and when the charging correction is not to be performed, inspection and measurement are performed without charging correction (S04). When the charging correction is to be performed, first, the charging correction to be performed is selected (S05). When a trajectory change due to an energy change is corrected, a control value is applied to the signal electron trajectory adjustment lens 9 to perform inspection and measurement (S06). When the trajectory change in which the signal electron distribution is asymmetric and the trajectory change in which the arrival position changes are corrected in addition to the trajectory change due to the energy change, the processing proceeds to step S07. When the control values of the stigmator 10 and the signal electron trajectory adjusting deflectors 11, 12, and 13 are not acquired, the control values of the stigmator 10 and the signal electron trajectory adjusting deflectors 11, 12, and 13 are acquired (S08). Thereafter, or when the control value is already acquired, inspection and measurement subjected to the charging correction are performed using these control values (S09).

The invention is not limited to the above embodiment, and includes various modifications. For example, the embodiments and the modification described above have been described in detail to facilitate understanding of the invention, and the invention is not necessarily limited to those including all the configurations described above. A part of a configuration of one embodiment or one modification can be replaced with a configuration of another embodiment or another modification, and a configuration of another embodiment or another modification can be added to a configuration of one embodiment or one modification. Another configuration may be added to a part of a configuration of each embodiment and each modification, or a part of a configuration of each embodiment and each modification may be deleted or replaced with another configuration.

What is claimed is:

1. A charged particle beam apparatus comprising:
an imaging unit configured to irradiate a sample with a charged particle beam and including a detector configured to detect signal electrons emitted from the sample; and
a computer configured to control the imaging unit, wherein
the imaging unit includes a signal electron trajectory adjustment lens configured to correct a signal electron trajectory of the signal electrons, and an optical element configured to correct the signal electron trajectory of the signal electrons and to be different from the signal electron trajectory adjustment lens,
a plurality of observation points are set in the sample, and
the computer sets a control value common to an observation point group which is a part or all of the plurality of observation points in the signal electron trajectory adjustment lens, and sets, for each of the observation points included in the observation point group, a control value for adjusting an arrival position of the signal electron trajectory corrected by the signal electron trajectory adjustment lens to the detector.

2. The charged particle beam apparatus according to claim 1, wherein
the optical element includes a stigmator configured to correct a deterioration of symmetry of a signal electron distribution on a detection surface of the detector.

3. The charged particle beam apparatus according to claim 2, wherein
the optical element includes a deflector configured to deflect the signal electrons.

4. The charged particle beam apparatus according to claim 1, wherein
the control value of the signal electron trajectory adjustment lens is set based on an energy width of a signal electron whose emission position is an observation point included in the observation point group.

5. The charged particle beam apparatus according to claim 1, wherein
the imaging unit includes
a primary optical system including a signal electron separation element and configured to irradiate the sample with charged particles from a charged particle source, and
a detection system in which signal electrons separated from an optic axis of the primary optical system by the signal electron separation element travel toward the detector.

6. The charged particle beam apparatus according to claim 5, wherein
the signal electron trajectory adjustment lens and the optical element are disposed in the detection system.

7. The charged particle beam apparatus according to claim 1, wherein
the computer stores a control value of the signal electron trajectory adjustment lens and a control value of the optical element.

8. The charged particle beam apparatus according to claim 1, wherein
the computer is configured to execute any one of a first inspection sequence in which an observation point of the sample is inspected or measured by correcting the signal electron trajectory by the signal electron trajectory adjustment lens, and a second inspection sequence in which an observation point of the sample is inspected or measured by correcting the signal electron trajectory by the signal electron trajectory adjustment lens and the optical element.
